(19) United States
(12) Patent Application Publication
(10) Pub. No.: US 2007/0082502 A1
(43) Pub. Date: Apr. 12, 2007

(54) Method for producing a dielectric layer on a carrier material and an integrated circuit comprising a capacitor incorporating a dielectric layer

(75) Inventors: Michael Gros-Jean, Grenoble (FR); Emilie Deloffre, Grenoble (FR); Christophe Wyon, Grenoble (FR)

Correspondence Address: JENKENS & GILCHRIST, PC, 1445 ROSS AVENUE, SUITE 3200, DALLAS, TX, 75202, US

(73) Assignees: STMicroelectronics S.A., Montrouge (FR); Commissariat a L'Energie Atomique, Paris (FR)

(21) Appl. No.: 11/524,504

(22) Filed: Sep. 20, 2006

(30) Foreign Application Priority Data
Sep. 21, 2005 (FR) 0509642

(51) Int. Cl. H01L 21/31; H01L 21/469

(52) U.S. Cl. 438/770; 438/771

(57) ABSTRACT

A dielectric material layer is formed on a carrier material. A gas mixture containing at least one precursor comprising a metallic element is alternately circulated with an oxidant gas in contact with the carrier material under first oxidizing conditions so as to form a first sub-layer having dielectric qualities. A gas mixture containing the same precursor then is circulated in contact with the first sub-layer under second oxidizing conditions being more strongly oxidizing than the first oxidizing conditions so as to form a second sub-layer having dielectric qualities.

### PRIORITY CLAIM

The present application claims priority from French Application for Patent No. 05 09642 filed Sep. 21, 2005, the disclosure of which is hereby incorporated by reference.

### BACKGROUND OF THE INVENTION

1. Technical Field of the Invention

The present invention relates to integrated circuits, and more particularly to the production of a layer including at least one dielectric material used, for example, for a capacitor.

2. Description of Related Art

It is known to produce planar or three-dimensional capacitors using a technology based on aluminum (Reactive Ion Etching, RIE) or based on copper (Damascene type integration).

The capacitors are conventionally obtained from a metal-insulator-metal (MIM) stack in which the lower electrode is a conductive material, for example TiN, the insulator is preferably a dielectric material with high permittivity (high-K material) and the upper electrode is a conductive material, for example TiN.

Such capacitors can be produced at the interconnections of an integrated circuit and, for example, after the fourth metallization level in the interconnections. The production of such capacitors actually within an integrated circuit thus still represents a difficulty, given that this production must not entail deterioration of the other components already produced.

Furthermore, the formation of a dielectric layer on a lower electrode also presents a certain number of problems.

Specifically, the steps for forming a dielectric layer are generally carried out under an oxidizing atmosphere in the high temperature range, preferably at temperatures above 350° C., in order to obtain a dielectric layer with good quality in terms of stoichiometry.

These formation steps generally entail oxidation of the lower electrode, however, causing its deterioration as well as the formation of an interface layer between the lower electrode and the dielectric layer. This interface layer may have a density greater than that of the dielectric layer and a thickness which may amount to 25 angstroms. When the dielectric material is an oxide, furthermore, oxidation of the lower electrode is accelerated owing to diffusion of oxygen from the oxide to the lower electrode, thereby increasing the thickness of the interface layer being formed.

These problems result in the appearance of leakage currents which, in particular, entail degradation of the electrical performance of the capacitor.

FR 2847593 thus describes the formation of a tantalum pentoxide layer on a carrier material in an oxidizing atmosphere at a temperature of between 300 and 350° C. from a gas mixture containing a tantalum precursor, the partial pressure of the precursor in the gas mixture being greater than or equal to 25 mTorr.

In view of the preceding, there is a need in the art to produce a dielectric layer having good quality in stoichiometric terms while minimizing the appearance of leakage currents.

### SUMMARY OF THE INVENTION

One embodiment provides a method for forming a layer having at least one dielectric material on a carrier material, in which:

a gas mixture, containing at least one precursor comprising a metallic element, then an oxidant gas are circulated in contact with the carrier material under first oxidizing conditions so as to form a first layer having at least one dielectric material, and

a gas mixture containing the precursor is circulated in contact with the first layer under second oxidizing conditions, the second oxidizing conditions being more strongly oxidizing than the first oxidizing conditions.

A dielectric layer with good quality in stoichiometric terms is then obtained while reducing to a minimum the thickness of the interface layer between the lower electrode and the dielectric layer.

The term first oxidizing conditions is intended to mean conditions which make it possible to minimize the oxidation of the lower electrode during the formation of the first layer consisting of at least one dielectric material.

These oxidizing conditions make it possible in particular to obtain an interface layer, arranged between the lower electrode and the first dielectric layer, which has a thickness of less than 5 angstroms.

In other words, the formation of the first layer having at least one dielectric material takes place under first oxidizing conditions which make it possible to minimize the oxidation of the lower electrode and, consequently, to reduce the thickness of the interface layer arranged between the lower electrode and the first layer having at least one dielectric material.

In this way, both an interface of good quality which limits the leakage currents of the dielectric layer and also satisfactory bulk properties are obtained.

Furthermore, the two steps of the method which were described above allow the electrical performance to be controlled better by controlling the interface between the lower electrode and the dielectric layer.

In particular, leakage currents can be obtained which are less than 3.10⁻⁵ amperes per cm² of dielectric at 125° C. under the application of a relative voltage equal to about 5 volts to the terminals of the electrodes, for a dielectric layer which has a thickness of 400 angstroms. These leakage currents are in particular about 100 times to 1000 times less than those generally measured for dielectric layers produced according to the conventional formation steps.

The oxidant gas advantageously contains water vapor in order to minimize the oxidation of the carrier material during the formation of the first layer.

As a variant, the carrier material is heated to a temperature of between 250 and 350° C. during the formation of the first layer and/or the first layer is formed with a plasma having a power of less than 150 watts, in order to work under less oxidizing conditions than during the formation of the second dielectric layer.

According to one embodiment, the gas mixture is circulated in a chamber in which the carrier material is placed, and in which the chamber is purged between the circulation of the gas mixture and the circulation of the oxidant gas during the formation of the first layer. Such a purging step makes it possible to reduce the concentration of the precursors which have not become attached on the surface of the carrier material. Furthermore, this purging step can make it possible to avoid oxidation reactions between the precursors which are not attached to the surface of the carrier material and the oxidant gas.

Preferably, the gas mixture is circulated in an oxidizing atmosphere after having formed a thickness between 5 and 1000 angstroms of the first layer.

According to one embodiment, a gas mixture, containing the precursor in an oxidizing atmosphere, and a plasma are circulated alternately in contact with the first layer, in order to obtain a dielectric layer of good quality in terms of stoichiometry.

Advantageously, the gas mixture contains tertbutylimido-tris-diethylamino tantalum (t-BuN=Ta(NEt₂)₃) or tantalum pentaethoxide (Ta(OEt)₅).

According to one characteristic, the carrier material is a semiconductor material or material comprising a metal.

Advantageously, the carrier material is selected from titanium nitride (TiN), tantalum nitride (TaN), copper, aluminum, tungsten, ruthenium, tungsten nitride (WN), tungsten carbonitride (WCN).

Advantageously, the dielectric material is selected from Ta₂O₅, Al₂O₃, TiO₂, ZrO₂ and/or HfO₂.

According to another aspect, the invention also relates to a layer consisting of at least one dielectric material, which can be obtained by the method described above.

According to another aspect, the invention also relates to an integrated circuit comprising at least one capacitor comprising a layer having at least one dielectric material arranged between two electrodes and obtained by the method described above.

According to one characteristic, an interface layer arranged between the electrode and the layer having at least one dielectric material has a thickness of less than 5 angstroms.

According to one characteristic, the layer consisting of at least one dielectric material has a thickness of between 20 and 2000 angstroms and, for a dielectric layer with a thickness equal to 400 angstroms, has a leakage current of less than 3.10⁻⁵ A/cm² at 125° C. under a relative voltage difference of about 5 volts applied between the two electrodes.

In an embodiment, a method for forming a dielectric material layer on a carrier material comprises circulating a gas mixture containing at least one precursor having a metallic element followed by an oxidant gas in contact with the carrier material under first oxidizing conditions so as to form a first dielectric material layer, and then circulating a gas mixture containing the same precursor in contact with the first layer under second oxidizing conditions so as to form a second dielectric material layer, the second oxidizing conditions being more strongly oxidizing than the first oxidizing conditions.

In an embodiment, a dielectric material layer comprises a first dielectric material sub-layer formed on a carrier material by alternately circulating a gas mixture containing at least one precursor having a metallic element and an oxidant gas under first oxidizing conditions, and a second dielectric material sub-layer formed on the first dielectric material sub-layer by circulating a gas mixture containing the same precursor under second oxidizing conditions being more strongly oxidizing than the first oxidizing conditions.

In another embodiment, a method for forming a dielectric material layer on a carrier material comprises: (a) circulating a gas mixture containing at least one precursor having a metallic element to form a monolayer on the carrier material; (b) applying an oxidant gas under first oxidizing conditions so as to oxidize the monolayer and form a first dielectric material sub-layer; and (c) circulating a gas mixture containing the same precursor in contact with the oxidized monolayer under second oxidizing conditions so as to form a second dielectric material sub-layer over the first dielectric material sub-layer, the second oxidizing conditions being more strongly oxidizing than the first oxidizing conditions.

### BRIEF DESCRIPTION OF THE DRAWINGS

A more complete understanding of the method and apparatus of the present invention may be acquired by reference to the following Detailed Description when taken in conjunction with the accompanying Drawings wherein:

FIG. 1 schematically illustrates an integrated circuit comprising a capacitor obtained according to one embodiment; and

FIGS. 2 to 4 schematically illustrate the steps of an embodiment of a layer consisting of at least one dielectric material.

### DETAILED DESCRIPTION OF THE PREFERRED EMBODIMENTS

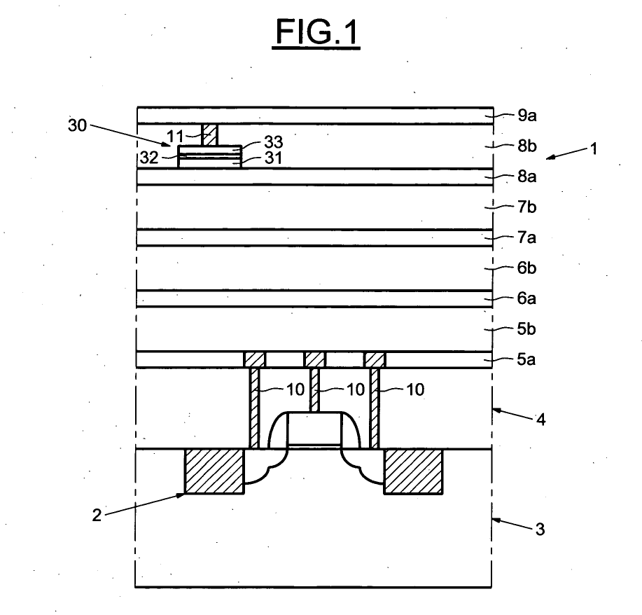

As illustrated in FIG. 1, an integrated circuit 1 comprises active components 2, for example transistors, in a substrate 3. The integrated circuit 1 also comprises stacked metallization levels 5a, 6a, 7a, 8a and 9a separated by dielectric layers 5b, 6b, 7b and 8b formed above the substrate 3. Arranged between the substrate 3 and the metallization level 5a, there is a dielectric layer 4 in which there are vias 10 providing the electrical connection of the active components 2.

A capacitor 30 has furthermore been produced between the metallization levels 8a and 9a of the integrated circuit 1. In other words, the capacitor 30 is situated in the dielectric layer 8b.

The capacitor 30 comprises a dielectric layer 32, for example a layer of tantalum pentoxide (Ta₂O₅), sandwiched between a lower electrode 31 resting on the upper surface of the metallization level 8a and an upper electrode 33 resting under the lower surface of the metallization level 9a. The electrodes 31 and 33 may consist of titanium nitride (TiN) or tungsten. A via 11 is arranged between the upper electrode 33 and the metallization level 9a, thus providing the electrical connection.

Under a relative voltage difference of about 5 volts applied between the two electrodes 31 and 33, a leakage current is measured which may be less than 3.10⁻⁵ A/cm² at a temperature of 125° C. for a dielectric layer which has a thickness of 400 angstroms. Furthermore, an X-ray analysis of the interface situated between the lower electrode 31 and the dielectric layer 32 can show that an interface layer is obtained whose thickness is in particular less than 5 angstroms.

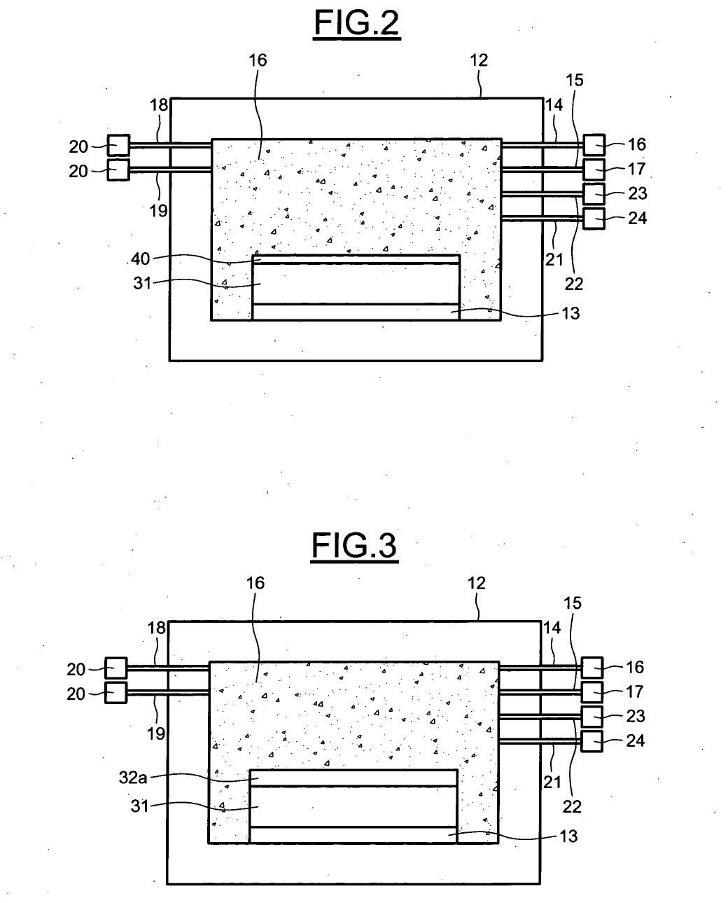

FIGS. 2 to 4 represent the principal steps of an embodiment making it possible to obtain a capacitor 30 having a dielectric layer 32 as described above and as illustrated in FIG. 1.

The fabrication is carried out by means of a chamber 12 in which a plate 13 is placed, the upper surface of which has a layer on top comprising a carrier material 31, for example of titanium nitride or tungsten, as represented in FIG. 2. Injection means 14 and 15, arranged in the walls of the chamber 12 and extending to above the plate 13, make it possible for a gas mixture 16 containing for example tertbutylimido-tris-diethylamino tantalum (t-BuN=Ta(NEt₂)₃) or tantalum pentaethoxide (Ta(OEt)₅) to be brought alternately into contact with the carrier material 31 in the chamber 12.

Purging means 18 and 19 are also arranged in the walls of the chamber 12.

The chamber 12 also comprises injection means 21 and 22, which will be used during a second step of the formation of the dielectric layer 32.

Thus, during a first step, the gas mixture 16 is injected into the chamber 12 through the injection means 14 so as to saturate the upper surface of the carrier material 31 in order to form a tantalum monolayer 40. After the formation of the tantalum monolayer 40, the interior of the chamber 12 is purged using the purging means 18 and 19. The purging may be carried out by circulating a gas 20 in the chamber 12, for example argon or nitrogen.

This purging makes it possible to minimize the concentration of free precursors which remain in the chamber 12 and which have not become attached on the surface of the carrier material 31 in order to form the tantalum monolayer 40. This purging can also make it possible to avoid a parasitic oxidation reaction between the free precursors and the oxidant gas 17.

Once the purging has been carried out, the oxidant gas 17 is circulated in contact with the carrier material 31 in order to oxidize the tantalum monolayer 40. A tantalum pentoxide (Ta₂O₅) monolayer 32a as represented in FIG. 3 is thereby formed. The oxidant gas 17 is preferably water vapor, so as to minimize the oxidation of the carrier layer 31.

Thus, the gas mixture 16 containing for example tertbutylimido-tris-diethylamino tantalum (t-BuN=Ta(NEt₂)₃) and the oxidant gas 17 are alternately circulated in contact with the carrier material 31 several times, each time with a purging step in between, in order to form a first tantalum pentoxide layer 32a with a thickness which may lie between 5 and 1000 angstroms.

This step of forming a first tantalum pentoxide layer 32a is carried out under weakly oxidizing conditions in order to reduce the risks of oxidizing the carrier material 31, and in order to minimize the formation of an interface layer between the carrier material 31 and the first tantalum pentoxide layer 32a. In other words, this first step makes it possible to control the quality of the interface between the carrier material 31 and the first tantalum pentoxide layer 32a and can make it possible to avoid oxidizing the carrier material 31.

Furthermore, the alternate circulation of the gas mixture 16 and the oxidant gas 17 also makes it possible to reduce the risks of oxidizing the carrier material.

As a variant, in order to engage weakly oxidizing conditions, the carrier material 31 may be heated to a heating temperature of between 250 and 350° C. by heating means (not shown in FIG. 2) which may be situated level with the plate 13.

As an alternative or in addition, oxygen assisted by a plasma with a power of less than 150 watts may also be circulated using an injection means (not shown in FIG. 2) during the formation of the first tantalum pentoxide layer 32a in order to engage weakly oxidizing conditions.

As another alternative or in addition, water vapor assisted by plasma or N₂O assisted by plasma with a power of less than 150 watts or a mixture of these plasma assisted gases may also be circulated, or even a mixture of these gases which is not plasma assisted.

The gas mixture 16 is subsequently circulated in contact with the tantalum pentoxide layer 32a under conditions more strongly oxidizing than the conditions for forming the first tantalum pentoxide layer 32a.

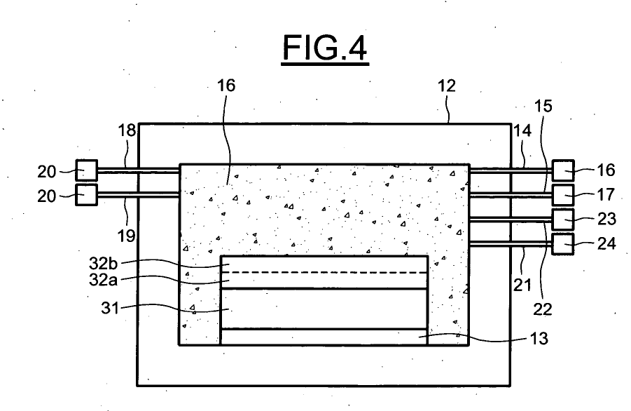

In this way, the gas mixture 16 is circulated in contact with the first tantalum pentoxide layer 32a in the chamber 12 by using an injection means 14, then an oxidant gas 23 is circulated there by using an injection means 22 as represented in FIG. 4. With a pausing time of a few milliseconds, preferably between 10 ms and 1000 ms, a plasma 24 is subsequently circulated by using an injection means 21. A tantalum pentoxide monolayer 32b is thereby formed.

The operation is repeated several times until a second tantalum pentoxide layer 32b is obtained with a sufficient thickness.

Oxygen is preferably used as the oxidant gas 23 in order to work under an oxidizing atmosphere during the formation of the second tantalum pentoxide layer 32b.

A plasma 24 which has a power of more than 150 watts is preferably used.

The tantalum pentoxide layer 32b may also be obtained by MOCVD deposition (metal organic chemical vapor deposition).

During this second step, a second tantalum pentoxide layer 32b is thereby formed which is positioned on the first tantalum pentoxide layer 32a.

This second step therefore takes place under conditions more strongly oxidizing than the conditions for forming the first tantalum pentoxide layer 32a.

This second step makes it possible to obtain a second tantalum pentoxide layer 32b which has a good quality in terms of stoichiometry. The second tantalum pentoxide layer 32b may, in particular, not have any oxygen vacancies.

Following the combination of these two steps, a tantalum pentoxide layer 32 with satisfactory bulk properties as well as a good interface is thereby obtained in contact with the carrier material 31. The tantalum pentoxide layer 32 has in particular a thickness of between 20 and 2000 angstroms and a quantity of impurities in particular less than 20%. The interface layer between the carrier material 31 and the dielectric layer 32 may have a thickness of less than 5 angstroms.

The leakage currents of the tantalum pentoxide layer 32 may in particular be 100 times less than the leakage currents measured for a tantalum pentoxide layer produced according to a MOCVD (metal organic chemical vapor deposition) method.

The capacitor 30 as represented in FIG. 1 is subsequently produced according to the conventional steps for obtaining a capacitor known to the person skilled in the art.

Such an embodiment may be employed in particular for semiconductor/dielectric/metal capacitor structures (MIS structures) or metal/dielectric/metal capacitor structures (MIM structures) for dynamic random-access memory applications.

Such an embodiment may also be employed in order to fabricate the gate oxide of an MOS transistor.

Although preferred embodiments of the method and apparatus of the present invention have been illustrated in the accompanying Drawings and described in the foregoing Detailed Description, it will be understood that the invention is not limited to the embodiments disclosed, but is capable of numerous rearrangements, modifications and substitutions without departing from the spirit of the invention as set forth and defined by the following claims.

What is claimed is:

1. A method for forming a dielectric material layer on a carrier material, comprising:
circulating a gas mixture containing at least one precursor having a metallic element followed by an oxidant gas in contact with the carrier material under first oxidizing conditions so as to form a first dielectric material layer, and
then circulating a gas mixture containing the same precursor in contact with the first layer under second oxidizing conditions so as to form a second dielectric material layer, the second oxidizing conditions being more strongly oxidizing than the first oxidizing conditions;
wherein circulating the gas mixture under second oxidizing conditions comprises alternately circulating a gas mixture, containing the precursor in an oxidizing atmosphere, and a plasma in contact with the first layer.

2. The method according to claim 1, wherein the oxidant gas contains water vapor.

3. The method according to claim 1, wherein the carrier material is heated to a temperature of between 250 and 350° C. during the formation of the first layer.

4. The method according to claim 1, wherein the first layer is formed with a plasma having a power of less than 150 watts.

5. The method according to claim 1, further comprising purging between the circulation of the gas mixture and the circulation of the oxidant gas during the formation of the first layer.

6. The method according to claim 1, circulating the gas mixture comprises circulating the gas mixture in an oxidizing atmosphere after having formed a thickness between 5 and 1000 angstroms of the first layer.

7. The method according to claim 1, wherein the gas mixture contains either tertbutylimido-tris-diethylamino tantalum (t-BuN=Ta(NEt₂)₃) or tantalum pentaethoxide (Ta(OEt)₅).

8. The method according to claim 1, wherein the carrier material is one of a semiconductor material or material comprising a metal.

9. The method according to claim 1, wherein the carrier material is selected from the group consisting of titanium nitride (TiN), tantalum nitride (TaN), copper, aluminum, tungsten, ruthenium, tungsten nitride (WN), tungsten carbonitride (WCN).

10. The method according to claim 1, wherein the dielectric material is selected from the group consisting of Ta₂O₅, Al₂O₃, TiO₂, ZrO₂ and/or HfO₂.

11. The method of claim 1 wherein the dielectric material layer is an insulating layer of an integrated circuit capacitor.

12. The method of claim 1 wherein the dielectric material layer is a gate oxide layer of an integrated circuit transistor.

13. The method of claim 1 wherein the first dielectric material layer has a thickness of about 5 angstroms.

14. The method of claim 13 wherein the first dielectric material layer has a thickness of less than 1000 angstroms.

15. The method of claim 1, wherein the dielectric material layer has a thickness of between 20 and 2000 angstroms.

16. The method of claim 15, wherein for a dielectric material layer with a thickness equal to about 400 angstroms, the dielectric material layer has a leakage current of less than 3.10⁻⁵ A/cm² at 125° C. under a relative voltage difference of about 5 volts applied between two electrodes separated by that 400 angstrom dielectric material layer.

17. A dielectric material layer comprising:
a first dielectric material sub-layer formed on a carrier material by alternately circulating a gas mixture containing at least one precursor having a metallic element and an oxidant gas under first oxidizing conditions; and
a second dielectric material sub-layer formed on the first dielectric material sub-layer by alternately circulating a gas mixture containing the same precursor and a plasma in contact with the first sub-layer under second oxidizing conditions being more strongly oxidizing than the first oxidizing conditions.

18. The dielectric material layer of claim 17 wherein that dielectric material layer is an insulating layer of an integrated circuit capacitor.

19. The dielectric material layer of claim 17 wherein that dielectric material layer is a gate oxide layer of an integrated circuit transistor.

20. The dielectric material layer of claim 17 wherein the first dielectric material sub-layer has a thickness of about 5 angstroms.

21. The dielectric material layer of claim 20 wherein the first dielectric material sub-layer has a thickness of less than 1000 angstroms.

22. The dielectric material layer of claim 17, wherein the dielectric material layer has a thickness of between 20 and 2000 angstroms.

23. The dielectric material layer of claim 22, wherein for a dielectric layer with a thickness equal to about 400 angstroms, the dielectric material layer has a leakage current of less than 3.10⁻⁵ A/cm² at 125° C. under a relative voltage difference of about 5 volts applied between two electrodes separated by that 400 angstrom dielectric material layer.

24. A method for forming a dielectric material layer on a carrier material, comprising:
(a) circulating a gas mixture containing at least one precursor having a metallic element to form a monolayer on the carrier material;
(b) applying an oxidant gas under first oxidizing conditions so as to oxidize the monolayer and form a first dielectric material sub-layer; and
(c) circulating a gas mixture containing the same precursor in contact with the oxidized monolayer under second oxidizing conditions so as to form a second dielectric material sub-layer over the first dielectric material sub-layer, the second oxidizing conditions being more strongly oxidizing than the first oxidizing conditions.

25. The method of claim 24 wherein the monolayer forms an interface between the carrier material and the dielectric material layer that is less than about 5 angstroms thick.

26. The method of claim 24 further comprising repeating alternately steps (a) and (b) to build a thicker first dielectric material sub-layer before performing step (c).

27. The method of claim 26 wherein the first dielectric material sub-layer has a thickness of between about 5-1000 angstroms and the dielectric material layer has a thickness of between about 20-2000 angstroms.

28. The method of claim 24, wherein the gas mixture contains either tertbutylimido-tris-diethylamino tantalum (t−BuN=Ta(NEt₂)₃) or tantalum pentaethoxide (Ta(OEt)₅).

29. The method of claim 24 wherein the dielectric material layer is an insulating layer of an integrated circuit capacitor.

30. The method of claim 24 wherein the dielectric material layer is a gate oxide layer of an integrated circuit transistor.
